(19) United States
(12) Patent Application Publication
(10) Pub. No.: US 2011/0006307 A1
(43) Pub. Date: Jan. 13, 2011

(54) Group III-Nitride Semiconductor Schottky Diode and Its Fabrication Method

(75) Inventors: Guan-Ting CHEN, Chiayi City (TW); Chia-Ming LEE, Toucheng Town (TW)

Correspondence Address: DAVID I. ROCHE;BAKER & MCKENZIE LLP, 130 EAST RANDOLPH DRIVE, CHICAGO, IL, 60601, US

(73) Assignee: TEKCORE CO., LTD., Nantou (TW)

(21) Appl. No.: 12/828,447

(22) Filed: Jul. 1, 2010

(30) Foreign Application Priority Data
Jul. 10, 2009 (TW) 098123533

(51) Int. Cl. H01L 29/872; H01L 29/205; H01L 21/329; H01L 29/20

(52) U.S. Cl. 257/76; 257/200; 438/572; 257/473; 257/E21.359; 257/E29.091; 257/E29.089; 257/E29.338

(57) ABSTRACT

A group III-nitride semiconductor Schottky diode comprises a conducting substrate having a first surface, a stack of multiple layers including a buffer layer and a semiconductor layer sequentially formed on the first surface, wherein the semiconductor layer comprises a group III nitride compound, a first electrode on the semiconductor layer, and a second electrode formed in contact with the first surface at a position adjacent to the stack of multiple layers. In other embodiments, the application also describes a method of fabricating the group III-nitride semiconductor Schottky diode.

### CROSS-REFERENCE TO RELATED APPLICATION

This application claims priority of Taiwan patent application no. 098123533, filed on Jul. 10, 2009.

### FIELD OF THE INVENTION

The present invention generally relates to Schottky diodes, and more particularly to a group III nitride semiconductor Schottky diode and its fabrication method.

### DESCRIPTION OF THE RELATED ART

Conventional diode elements include P—N junction diodes and metal-semiconductor junction diodes. The structure of a P—N junction diode usually comprises p-type and n-type semiconductors that are formed adjacent to each other to form a P—N junction. Instead of p-type and n-type semiconductors, a metal-semiconductor junction diode uses two different types of materials to form a metal-semiconductor junction. The Schottky diode is a well known diode structure that uses a metal-semiconductor junction. Such Schottky diodes can usually serve as a rectifier element.

A Schottky diode generally uses a metal and a lightly doped semiconductor that are formed adjacent to each other for forming a Schottky contact. The work function difference between metal and semiconductor results in a potential barrier. Therefore, upon application of a suitable voltage bias, the Schottky diode can easily become a one-way conductor, which can be used as rectifying contact. Because carrier storage effect can be substantially reduced, the Schottky diode allows high conduction when forward biased and effectively blocks conduction when reversely biased, and is capable of fast switching between positive and negative biases. That is one reason that Schottky diodes are often used in devices that need fast switching speeds and low current leakage.

Conventionally, a Schottky diode is formed on an insulating sapphire substrate. Multiple n-type doped semiconductor layers (often comprising GaN or other similar materials) are formed on the insulating sapphire substrate by epitaxy growth. Then, at least two layers of metal are formed on the semiconductor layers at different positions to serve as the cathode and anode of the Schottky diode.

Despite the aforementioned advantages, known drawbacks of the Schottky diode include its fabrication cost and a larger device surface area. Moreover, because the cathode and the anode are in contact with the semiconductor, the insulating sapphire substrate may affect the thermal dissipation of the diode, which can deteriorate the operational characteristics of the diode and limits its the range of application.

As a result, there is a need for a group III nitride Schottky diode that can be fabricated in a cost-effective manner, and address at least the foregoing issues.

### SUMMARY

The present application describes a group III-nitride semiconductor Schottky diode and its fabrication method. In one embodiment, the group III-nitride semiconductor Schottky diode comprises a conducting substrate having a first surface, a stack of multiple layers including a buffer layer and a semiconductor layer sequentially formed on the first surface, wherein the semiconductor layer comprises a group III nitride compound, a first electrode on the semiconductor layer, and a second electrode formed in contact with the first surface at a position adjacent to the stack of multiple layers.

In other embodiments, the group III-nitride semiconductor Schottky diode comprises a conducting substrate having a first surface and a second surface opposite to each other, a stack of multiple layers comprising a buffer layer and a semiconductor layer sequentially formed on the first surface, wherein the semiconductor layer comprising a group III nitride compound, a first electrode formed in contact with the semiconductor layer, and a second electrode formed in contact with the second surface.

The present application also describes a method of fabricating a Schottky diode. The method comprises providing a conducting substrate having a first surface and a second surface opposite to each other, forming a stack of multiple layers comprising a buffer layer and a semiconductor layer on the first surface, wherein the semiconductor layer comprising a group III nitride compound, forming a first electrode on the semiconductor layer, and forming a second electrode on an exposed region of either of the first surface and the second surface.

At least one advantage of the structure and method described herein is the ability to provide a Schottky diode in which electric current can flow through the substrate. Since the substrate has large surface area, more devices can be arranged on the substrate. In addition, the conductivity and thermal dissipation can be improved through the substrate.

### BRIEF DESCRIPTION OF THE DRAWINGS

FIG. 1A is a schematic view illustrating one embodiment of a group III-nitride semiconductor Schottky diode;

FIG. 1B is a schematic view illustrating two Schottky diodes in series connection;

FIG. 1C is a cross-sectional view taken along section line 1C shown in FIG. 1B;

FIG. 1D is a schematic view illustrating another embodiment of a group III-nitride semiconductor Schottky diode;

FIGS. 2A through 2E are schematic views illustrating method steps for fabricating a group III-nitride semiconductor Schottky diode; and

FIG. 2F is a schematic view illustrating a group III-nitride semiconductor Schottky diode fabricated in accordance with another embodiment.

### DETAILED DESCRIPTION OF THE EMBODIMENTS

The present application describes a Schottky diode and its fabrication method. The Schottky diode includes a conducting substrate having a surface on which is formed at least one electrode. An ohmic contact is thereby formed between the conducting substrate and electrode, permitting electric current flow. As a result, when the Schottky diode is in a conducting state, electric current can flow through the substrate. Owing to the large surface area of the substrate, conductivity and thermal dissipation can be improved during operation. As a result, damages induced by overheating can be prevented, and operational characteristics of the Schottky diode can be enhanced. In certain embodiments, the cathode and anode of the Schottky diode can be arranged either on a same side of the substrate, or on opposite sides of the substrate for reducing the size of the Schottky diode.

The term “group III nitride” used herein refers to compounds that include nitrogen (N) and elements in the group III in the periodic table, such as aluminum (Al), gallium (Ga) and Indium (In), and any ternary or quaternary compounds thereof (e.g., AlGaN or AlInGaN).

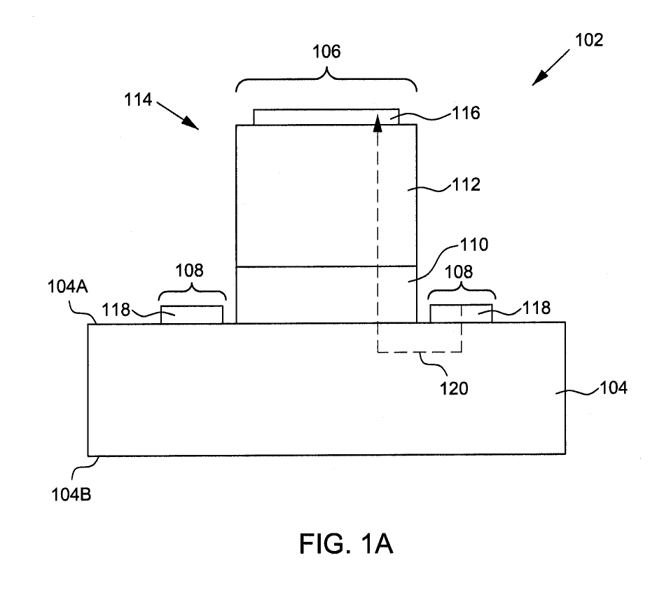

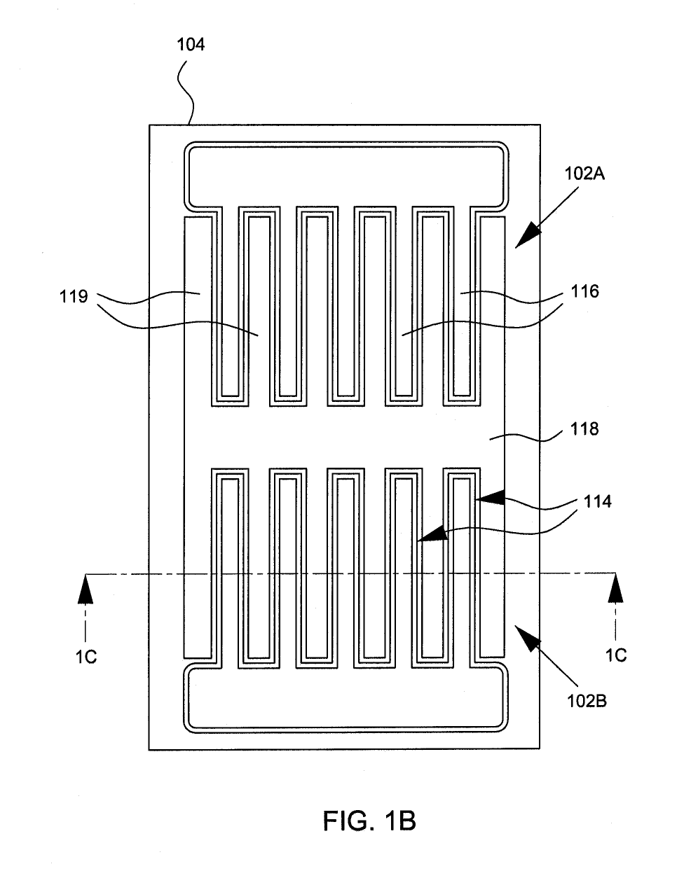

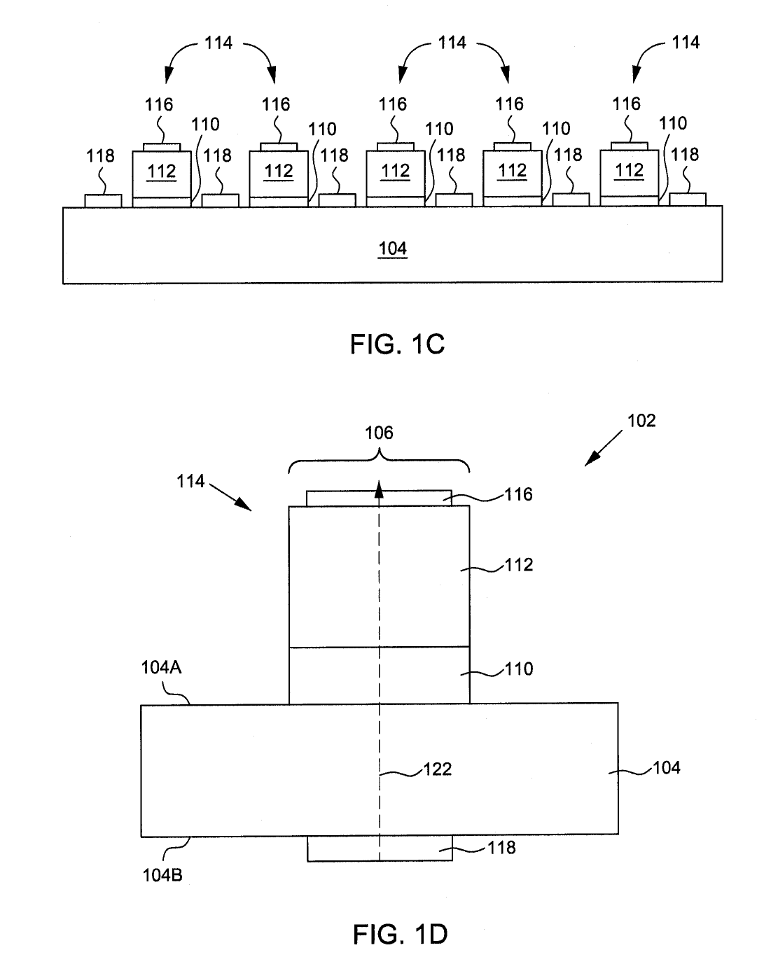

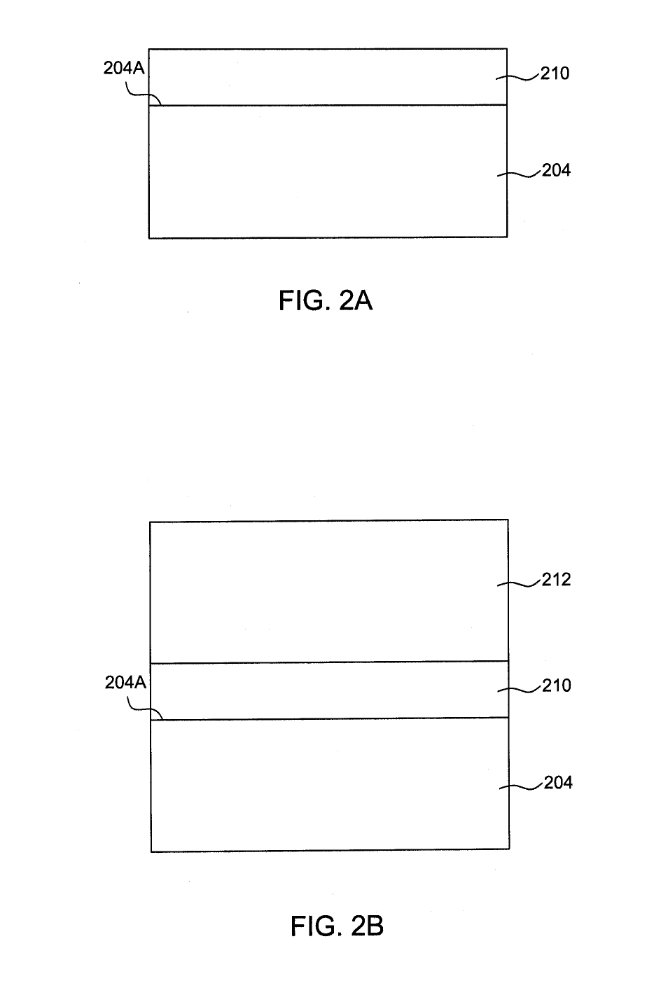

FIG. 1A is a schematic view illustrating one embodiment of a Schottky diode 102. The Schottky diode 102 includes a substrate 104 having a first surface 104A, and a second surface 104B opposite the first surface 104A. The substrate 104 is made of a conducting material, such as silicon (Si), gallium arsenide (GaAs), silicon carbide (SiC), or like materials. The first surface 104A includes a first region 106 and a second region 108 adjacent to each other. A plurality of layers are stacked on the first surface 104A of the substrate 104 in the first region 106 for forming an active region 114 made of a stack of multiple layers. In one embodiment, the stack of layers can include a buffer layer 110 and a semiconductor layer 112 respectively stacked up in sequence on the substrate 104. The buffer layer 110 formed on the substrate 104 can be used for reducing lattice mismatch between the substrate 104 and the semiconductor layer 112, thereby yielding better crystalline quality for the semiconductor layer 112. Examples of material that can be used for the buffer layer 110 can comprise silicon doped aluminum gallium nitride (AlₓGa₁₋ₓN) or like group III nitride compounds, wherein the parameter x (aluminum ratio) can be between 0 and 1. Examples of material for the semiconductor layer 112 can include gallium nitride (GaN) and like group III nitride compounds. Although the illustrated embodiment only shows the buffer layer 110 and the semiconductor layer 114 in the active region 114, other material layers can also be incorporated in the active region 114.

On top of the active region 114 is formed a first electrode 116, which can be used as an anode of the Schottky diode 102. The interface of the first electrode 116 with the semiconductor layer 112 forms a Shottky barrier region. The first electrode 116 can have a single or multi-layer structure. Suitable materials for forming the first electrode 116 include metals that are good conductors, easy for welding, and have good bonding with the semiconductor layer 112 for forming a Schottky contact. Examples of metals that can be used for the first electrode 116 can include aluminum, platinum, gold, nickel, and molybdenum.

A second electrode 118 is formed on the first surface 104A of the substrate 104 in the second region 108 for forming an ohmic contact between the second electrode 118 and the substrate 104. The second electrode 118 can be used as a cathode of the Schottky diode 102. The second electrode 118 can have a single or multi-layer structure. Suitable materials for the second electrode 118 include metals that are good conductors, easy for welding, and have good bonding with the conducting substrate 104 for forming an ohmic contact. Examples of suitable metals can include aluminum.

When the Schottky diode 102 is in a conducting state, an electric current can flow along a direction 120 laterally from the second electrode 118 in the second region 108 laterally through the substrate 104, and then vertically through the buffer layer 110, the semiconductor layer 112 and the first electrode 116 in the first region 106. Because the electric current can flow through the conducting substrate 104, conductivity and thermal dissipation through the substrate 104 can be promoted. As a result, device damages induced by overheating can be prevented, and operational characteristics of the Schottky diode can be enhanced. The aforementioned advantages can be further enhanced by using a substrate 104 having a larger surface area, which also allows more devices to be formed on the first surface 104A of the substrate 104.

While the aforementioned embodiment describes one Schottky diode, the same design and benefits can also be applied for diverse circuit implementation using Schottky diodes.

FIG. 1B is a schematic planar view illustrating an embodiment of Schottky diodes in series connection, and FIG. 1C is a cross-sectional view taken along section line 1C in FIG. 1B. As shown in FIGS. 1B and 1C, Schottky diodes 102A and 102B can be in series connection on the conducting substrate 104. The active region 114 and first electrode 116 of each of the Schottky diodes 102A and 102B can have a portion formed in a comb-shape. The second electrode 118 (i.e., the cathode), which is formed on the substrate 104, is located in a region between the Schottky diodes 102A and 102B. More specifically, the second electrode 118 can include finger-shaped portions 119 that extend through a plurality of interstices left in the comb-shaped portion of each active region 114. As shown in FIG. 1C, an alternated layout of the first and second electrodes 116 and 118 can be thereby obtained for serially connecting each other the Schottky diodes 102A and 102B.

During operation, electric currents can flow laterally from the second electrode 118 through the substrate 104, and then vertically through the buffer layer 110, the semiconductor layer 112 and the first electrode 116.

FIG. 1D is a schematic view illustrating another embodiment of a Schottky diode 102. The layer structure of the island-shaped active region 114 may be similar to the previous embodiment illustrated in FIG. 1A. The second electrode 118, however, is formed on the second surface 104B of the substrate 104 opposite to the active region 114. When the Schottky diode 102 is in a conducting state, electric current can flow from the second electrode 118 along a vertical direction 122 that passes through the thickness of the substrate 104, the buffer layer 110, the semiconductor layer 112 and the first electrode 116. With the aforementioned vertical structure, the surface area occupied by the Schottky diode 102 on the substrate 104 can be reduced. As a result, the number of devices that can be formed on the substrate 104 can be advantageously increased.

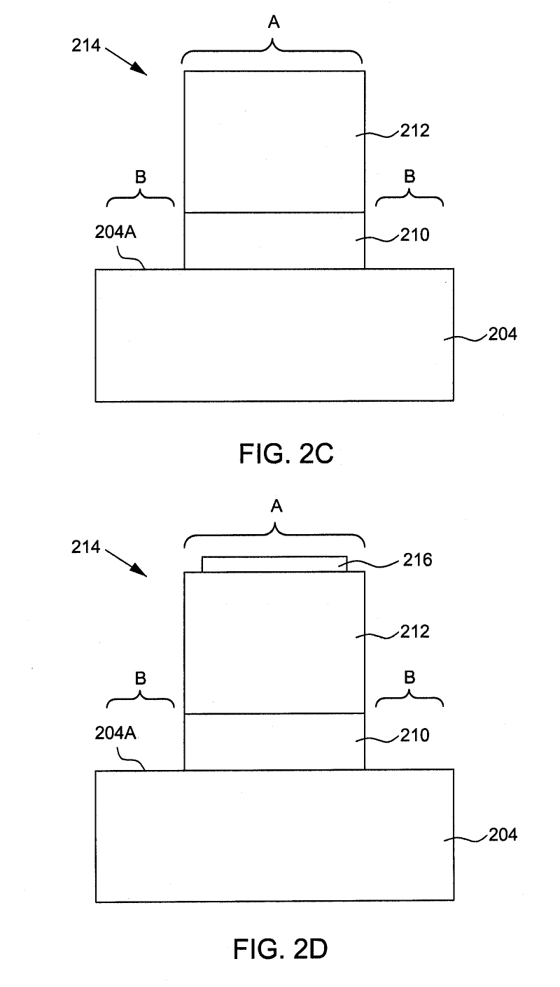

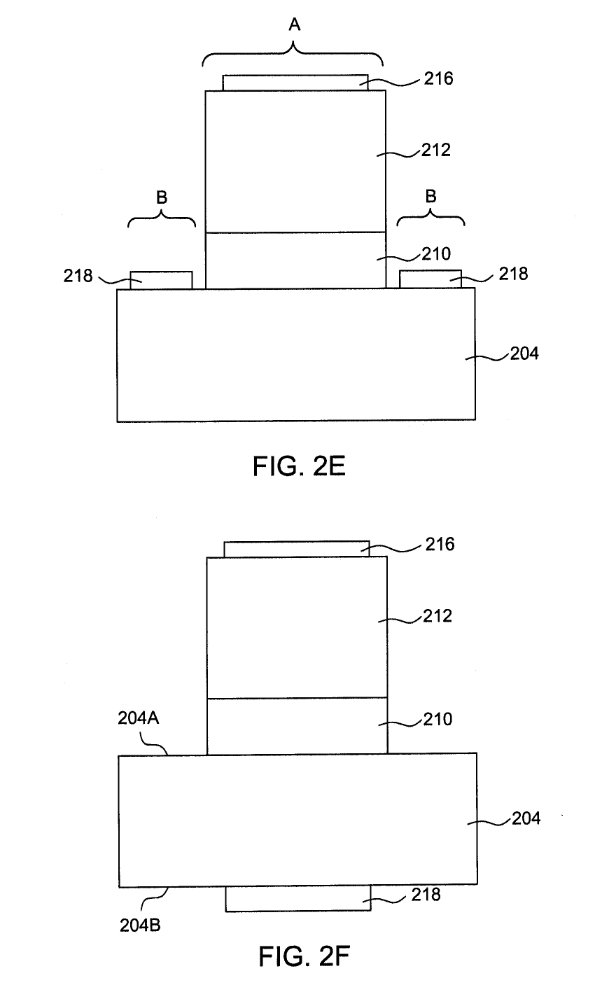

FIGS. 2A through 2E are schematic views illustrating a method of fabricating a group III-nitride semiconductor Schottky diode. First, with reference to FIG. 2A, a conducting substrate 204 (e.g., a doped silicon substrate) can be placed in a reactive chamber of a metal-organic chemical vapor deposition chamber. Reacting gases can then be fed in the deposition chamber for forming a buffer layer 210 on a first surface 204A of the substrate 204. In one embodiment, the reacting gases can include trimethyl-gallium supplied at a flow rate between about 100 and 200 sccm (standard cubic centimeter per minute), trimethyl-aluminum supplied at a flow rate between about 50 and 100 sccm, and ammonia at a flow rate between about 10 and 20 liters per minute. The chamber can be kept under a pressure of about 500 mbar, and at a temperature between about 600 and 1200. A buffer layer 210 comprising of aluminum gallium nitride (AlₓGa₁₋ₓN) can be thereby formed by epitaxy growth on the first surface 204A of the substrate 204, wherein the ratio of aluminum x is between 0 and 1, and the thickness of the buffer layer 210 can be between about 10 and 1000 angstroms. By precisely controlling the thickness and conditions of the epitaxy growth for the buffer layer 210, higher crystalline quality can be obtained for the semiconductor layer subsequently formed on the buffer layer 210, which can yield enhanced conductivity.

Referring to FIG. 2B, a semiconductor layer 212 comprising gallium nitride (GaN) then can be formed on the buffer layer 210. In one embodiment, the reacting gases used for forming the semiconductor layer can include trimethyl-gallium fed at a flow rate between about 100 and 500 sccm, trimethyl-aluminum fed at a flow rate between about 50 and 100 sccm, and ammonia fed at a flow rate between about 10 and 20 liters per minute. The chamber can be kept under a pressure of about 200 mbar, and at a temperature between about 1000 to 1200. A semiconductor layer 212 comprising of gallium nitride is thereby formed by epitaxy growth on the buffer layer 210 with a thickness between about 1 and 10 micrometers (μm). After epitaxy growth of the semiconductor layer 212, the substrate 204 can be removed from the deposition chamber.

Referring to FIG. 2C, the substrate 204 then can be processed in another processing chamber for etching and further deposition steps. A photo-resist layer (not shown) can be formed on the surface of substrate 204. Photolithography and developing processes can be conducted to define a region A in the photo-resist layer corresponding to the island-shaped active region. An etching process is then applied for removing portions of the semiconductor layer 212 and the buffer layer 210 not covered by the photo-resist layer until a region B on the first surface 204A of the substrate 204 is exposed. A island-shaped active region 214 can be thereby formed on the first surface 204A of the substrate 204, comprising a stack of multiple layers comprising the semiconductor layer 212 and the buffer layer 210.

Referring to FIG. 2D, a first electrode 216 can then be formed by evaporation on the semiconductor layer 212. The first electrode 216 comprises of aluminum, platinum, gold, nickel, molybdenum, or like metals, with a thickness between about 300 and 3000 angstroms. The first electrode 216 can be used as an anode that is in Shottky contact with the semiconductor layer 212.

Next referring to FIG. 2E, a second electrode 218 can be formed by electron-beam evaporation on the first surface 204A of the substrate 204 in the exposed region B. Suitable materials for the second electrode 218 include metals that are good conductors, easy for welding, and have good bonding with the conducting substrate 204 for forming an ohmic contact. Examples of suitable metals can include aluminum. The thickness of the second electrode 218 can be about 20,000 angstroms. An ohmic contact can be thereby formed at the interface between the substrate 204 and the second electrode 218 serving as a cathode. A Schottky diode can be thereby formed with the first and second electrode 216 and 218 located on a same side of the substrate 204.

As shown in FIG. 2F, in an alternate embodiment, the second electrode 218 can also be formed on the second surface 204B of the substrate 204 opposite to the active region 214 for forming a vertical Schottky diode. In this case, electric current can flow vertically between the first electrode 216 and the second electrode 218 and through the thickness of the substrate 204.

As described above, the Schottky diode forms an ohmic contact between one of its electrode and the conducting substrate. As a result, electric current can flow through the substrate during operation of Schottky diode. Since the substrate can have a large surface area, more devices can be arranged on the substrate. In addition, electrical conductivity and thermal dissipation through the substrate can be improved, avoiding damages induced by overheating and improving the operational characteristic of the Schottky diode.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A group III-nitride semiconductor Schottky diode comprising:
a conducting substrate having a first surface;
a stack of multiple layers including a buffer layer and a semiconductor layer sequentially formed on the first surface, wherein the semiconductor layer comprises a group III nitride compound;
a first electrode on the semiconductor layer; and
a second electrode formed in contact with the first surface at a position adjacent to the stack of multiple layers.

2. The group III-nitride semiconductor Schottky diode according to claim 1, wherein the conducting substrate is a silicon substrate, n-doped silicon substrate, gallium arsenide substrate, or silicon carbide substrate.

3. The group III-nitride semiconductor Schottky diode according to claim 1, wherein the buffer layer includes a material compound comprising aluminum gallium nitride or like group III nitride compound.

4. The group III-nitride semiconductor Schottky diode according to claim 1, wherein the thickness of the buffer layer is between about 10 and 1000 angstroms.

5. The group III-nitride semiconductor Schottky diode according to claim 1, wherein the second electrode includes aluminum.

6. The group III-nitride semiconductor Schottky diode according to claim 1, wherein the group III nitride compound includes gallium nitride.

7. The group III-nitride semiconductor Schottky diode according to claim 1, wherein the thickness of the semiconductor layer is between about 1 and 10 μm.

8. A group III-nitride semiconductor Schottky diode comprising:
a conducting substrate, comprising a first surface and a second surface opposite to each other;
a stack of multiple layers comprising a buffer layer and a semiconductor layer sequentially formed on the first surface, wherein the semiconductor layer comprising a group III nitride compound;
a first electrode formed in contact with the semiconductor layer; and
a second electrode formed in contact with the second surface.

9. The group III-nitride semiconductor Schottky diode according to claim 8, wherein the conducting substrate is a silicon substrate, n-doped silicon substrate, gallium arsenide substrate, or silicon carbide substrate.

10. The group III-nitride semiconductor Schottky diode according to claim 8, wherein the buffer layer includes a material compound comprising aluminum gallium nitride or like group III nitride compounds.

11. The group III-nitride semiconductor Schottky diode according to claim 8, wherein the thickness of the buffer layer is between about 10 and 1000 angstroms.

12. The group III-nitride semiconductor Schottky diode according to claim 8, wherein the second electrode includes aluminum.

13. The group III-nitride semiconductor Schottky diode according to claim 8, wherein the group III nitride compound includes gallium nitride.

14. The group III-nitride semiconductor Schottky diode according to claim 8, wherein the thickness of the semiconductor layer is between about 1 and 10 μm.

15. A method of fabricating a Schottky diode, comprising:
providing a conducting substrate having a first surface and a second surface opposite to each other;
forming a stack of multiple layers comprising a buffer layer and a semiconductor layer on the first surface, wherein the semiconductor layer comprising a group III nitride compound;
forming a first electrode on the semiconductor layer; and
forming a second electrode on an exposed region of either of the first surface and the second surface.

16. The method according to claim 15, wherein the conducting substrate is silicon substrate, n-doped silicon substrate, gallium arsenide substrate, or silicon carbide substrate.

17. The method according to claim 15, wherein the second electrode is in contact with the first surface at a position adjacent to the stack of multiple layers.

18. The method according to claim 15, wherein the second electrode is formed in contact with the second surface at a position opposite to the stack of multiple layers.

19. The method according to claim 15, wherein the thickness of the buffer layer is between about 10 and 1000 angstrom.

20. The method according to claim 15, wherein the second electrode includes aluminum.
